(19) United States
(12) Patent Application Publication
(10) Pub. No.: US 2022/0059439 A1
(43) Pub. Date: Feb. 24, 2022

(54) SOLDER PRINTING

(71) Applicant: Texas Instruments Incorporated, Dallas, TX (US)

(72) Inventors: Robert Allan Neidorff, Bedford, NH (US); Benjamin Cook, Addison, TX (US); Stefan Herzer, Marzling (DE)

(73) Assignee: Texas Instruments Incorporated, Dallas, TX (US)

(21) Appl. No.: 17/000,146

(22) Filed: Aug. 21, 2020

(51) Int. Cl. H01L 23/495; H01L 21/56; H01L 23/00

(52) U.S. Cl. CPC H01L 23/49582; H01L 21/561; H01L 24/83; H01L 24/29; H01L 2224/29076; H01L 2224/29111; H01L 2224/29139; H01L 2224/29147; H01L 2224/83815

(57) ABSTRACT

A method includes performing a non-screen printing process that deposits solder on a lead frame or on conductive features of a semiconductor die or wafer, or on or in a conductive via of a laminate structure. The method further comprises engaging the semiconductor die to the lead frame, performing a thermal process that reflows the solder, performing a molding process that forms a package structure which encloses the semiconductor die and a portion of the lead frame, and separating a packaged electronic device from a remaining portion of the lead frame.

### BACKGROUND

Packaged electronic devices include integrated circuits (ICs) and single component devices with a semiconductor die and a package structure with externally accessible leads for connection to a printed circuit board or socket. Some packaging types include a starting lead frame with metal structures for final product leads and bond wire connections between die bond pads and the leads. Ball grid array (BGA) devices have solder balls connected to copper pads of a substrate or interposer structure, such as a printed circuit board (PCB) to which the die is attached. Wafer level chip scale packages (WCSP) include a die with electrode pads, such as copper pads or posts soldered to a conductive redistribution layer (RDL). Tin-silver (Sn, Ag) solder is often plated on select portions of a lead frame for subsequent soldering to copper posts of a semiconductor die. Although Sn, Ag solder can be plated to facilitate compact package designs, it has limited current capacity and Sn, Ag solder connections from die copper posts to a lead frame or from die copper posts to a WCSP RDL can fail due to electromigration. Tin-silver-copper (Sn, Ag, Cu or SAC solder) has better current capacity than Sn, Ag solder, but does not work in plating applications. SAC solder can be screen printed, but this approach suffers from misalignment and manufacturability issues.

### SUMMARY

In accordance with one aspect, a method includes performing a non-screen printing process that deposits solder on a lead frame or on conductive features of a semiconductor die or wafer, or on or in a conductive via of a laminate structure. In one example, the non-screen printing process deposits solder on the lead frame or on conductive features of the semiconductor die or wafer, and the method also includes engaging the semiconductor die to the lead frame, performing a thermal process that reflows the solder, performing a molding process that forms a package structure which encloses the semiconductor die and a portion of the lead frame, and separating a packaged electronic device from a remaining portion of the lead frame. In one example, the method further includes depositing flux on the solder after performing the non-screen printing process and before engaging the semiconductor die to the lead frame. In one implementation, the flux is deposited by performing a second non-screen printing process that deposits the flux on the solder. In one example, the non-screen printing process deposits the solder mixed with flux. In one example, the non-screen printing process deposits the solder as an alloy of tin (Sn), silver (Ag), and copper (Cu). In one example, the non-screen printing process deposits the solder as an alloy mixture of melted particles using a heated print head. In one example, the non-screen printing process deposits the solder as particles in a solvent. In one implementation, the non-screen printing process deposits the solder using: a first print head that deposits tin particles in a first solvent; a second print head that deposits silver particles in a second solvent; and a third print head that deposits copper particles in a third solvent. In one example, the non-screen printing process deposits the solder as an alloy by: printing melted first particles using a heated first print head; and printing melted second particles using a heated second print head. In one example, the non-screen printing process is an inkjet printing process. In one example, the non-screen printing process is an electrostatic printing process. In one example, the non-screen printing process deposits the solder using a first print head that deposits first particles in a first solvent, and a second print head that deposits second particles in a second solvent.

In another aspect, a method includes performing a non-screen printing process that deposits solder on an uneven surface of a lead frame or on an uneven surface of a lead of a packaged electronic device. In one example, the non-screen printing process is an inkjet printing process. In one example, the non-screen printing process is an electrostatic printing process. In one example, performing the non-screen printing process includes controlling a spacing distance between a print head and the uneven surface of the lead frame or the uneven surface of the lead of the packaged electronic device according to a contour of the uneven surface.

In another aspect, a method includes performing a non-screen printing process that deposits solder on or in a conductive via of a laminate structure. In one example, the non-screen printing process is an inkjet printing process. In one example, the non-screen printing process is an electrostatic printing process.

In another aspect, an electronic device comprises a conductive structure of a lead frame or semiconductor die or wafer or substrate, and a solder layer on the conductive structure, the solder layer comprising co-diffused metallic nanoparticles of two metals, the nanoparticles having respective diameters of 20 nm or more and 20 um or less. In one example, a ratio of concentrations of the two metals in the solder layer varies along at least one direction.

### BRIEF DESCRIPTION OF THE DRAWINGS

FIG. 1 is a flow diagram of a method of manufacturing a packaged electronic device.

FIG. 2 is a flow diagram of one example non-screen solder printing process in the method of FIG. 1.

FIG. 3 is a flow diagram of another example non-screen solder printing process in the method of FIG. 1.

FIG. 4 is a flow diagram of another example non-screen solder printing process in the method of FIG. 1.

FIG. 5 is a flow diagram of another example non-screen solder printing process in the method of FIG. 1.

FIGS. 6-16 are partial sectional side elevation views of a packaged electronic device undergoing fabrication according to the method of FIGS. 1 and 5.

FIG. 17 is a perspective view of the packaged electronic device of FIGS. 6-16.

FIGS. 18 and 19 are partial sectional side elevation views of a lead frame with an etched stepped contour undergoing non-screen solder printing deposition according to another example of the method of FIG. 1.

FIG. 20 is a partial sectional side elevation view of a singulated packaged electronic device with saw cut leads having angled contours undergoing non-screen solder printing deposition according to another example of the method of FIG. 1.

FIG. 21 is a partial sectional side elevation view of a laminated structure with conductive vias undergoing non-screen solder printing deposition according to another example of the method of FIG. 1.

FIGS. 22-27 are partial sectional side elevation views of another singulated packaged electronic device with saw cut leads having angled contours undergoing non-screen solder printing deposition and thermal processing to form a packaged electronic device having varying lateral and vertical solder constituent ratios across the film and vertically through the film according to another example of the method of FIG. 1.

FIG. 28 is a partial sectional side elevation view of the packaged electronic device of FIGS. 22-27 with varying SAC ratios across the film and vertically through the solder.

FIGS. 29-46 illustrate several non-limiting examples of profile ratios of two metal constituents of example printed and thermally co-diffused solder layers formed on respective conductive features of a packaged electronic device.

### DETAILED DESCRIPTION

In the drawings, like reference numerals refer to like elements throughout, and the various features are not necessarily drawn to scale. One or more operational characteristics of various circuits, systems and/or components are hereinafter described in the context of functions which in some cases result from configuration and/or interconnection of various structures when circuitry is powered and operating.

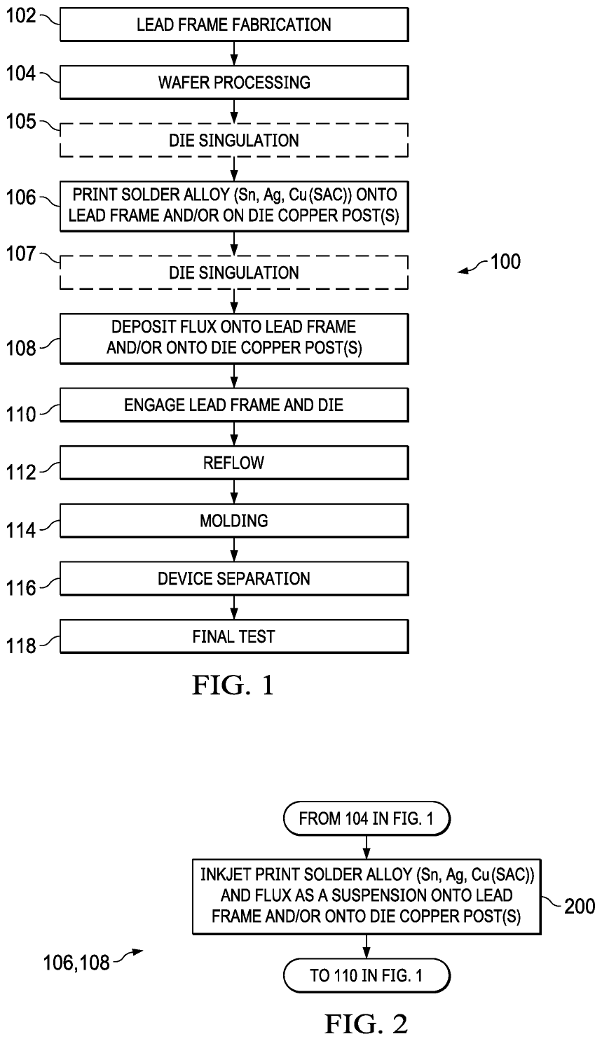

FIG. 1 shows a method 100 that can be used for manufacturing a packaged electronic device. The method 100 includes, inter alfa, printing solder on a lead frame or on conductive features of a semiconductor die or wafer, and/or on or in a conductive via. Described examples use non-screen printing processes including without limitation jet printing, offset or transfer printing, electrostatic printing, etc. The non-screen printing process in certain implementations includes ink jet or electrostatic printing techniques and one or more printheads to provide controlled placement and composition of the printed solder, alone or in combination with print deposition of solder flux in an electronic device manufacturing process to facilitate small packages and small feature sizes, without requiring lead frame plating, and allowing the use of a variety of solder alloys, including SAC solder for better current capacity compared to Sn, Ag solder. The method 100 includes lead frame fabrication at 102, as well as wafer processing at 104. The illustrated example includes solder alloy printing before or after die singulation.

In one implementation, die singulation is performed at 105, followed by printing solder printing at 106. In another implementation, solder printing is performed at 106, followed by die singulation at 107. In one example, the solder printing at 106 includes printing a solder alloy (e.g., SAC of any desired stoichiometry) onto the lead frame and/or onto die copper posts of the processed wafer or singulated die. At 108, the method 100 includes depositing flux on the printed solder, such as by dipping, printing, dispensing, etc. The lead frame is engaged to the die at 110, and reflow processing is performed at 112. A molding operation or process is performed at 114, followed by device separation at 116 and any desired final test at 118.

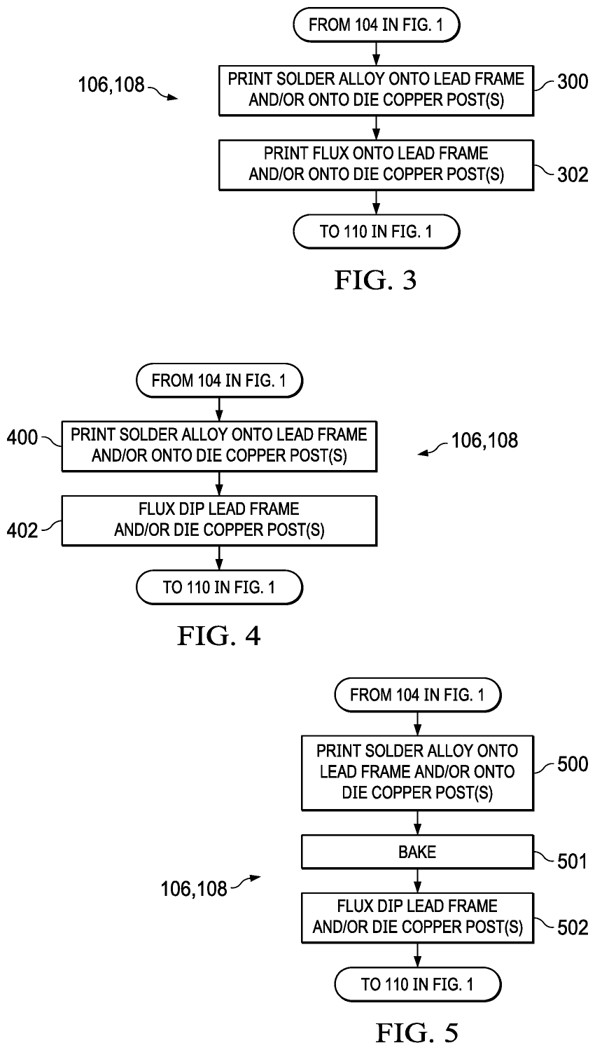

FIGS. 2-5 show different example solder and/or flux deposition examples that can be used at 106 and 108 in FIG. 1. FIG. 2 shows one example non-screen solder printing processing 200 that can be used at 106 and 108 in FIG. 1. This example includes inkjet printing a solder alloy and flux as a suspension onto the lead frame and/or onto die copper posts of the processed wafer or singulated die. In one implementation, the solder alloy is a tin, silver, copper (e.g., SAC) alloy of any desired stoichiometry. FIG. 3 shows another example non-screen solder printing process 300, 302 that can be used at 106 and 108 in the method 100 of FIG. 1. This example includes printing a solder alloy (e.g., SAC) onto the lead frame and/or onto die copper posts at 300, and printing flux at 302 onto the lead frame and/or onto the die copper posts. FIG. 4 shows another example non-screen solder printing process 400, 402 that can be used at 106 and 108 in the method 100 of FIG. 1. This example includes printing a solder alloy onto the lead frame and/or onto die copper posts at 400, and flux dipping the lead frame and/or die copper posts at 402. FIG. 5 shows another example non-screen solder printing process 500, 501, 502 that can be used at 106 and 108 in FIG. 1. At 500, the solder alloy is printed at 500 onto the lead frame and/or onto the die copper posts. In this example, the printed solder alloy is baked at 501. At 502, the lead frame and/or die copper posts is/are dipped in flux.

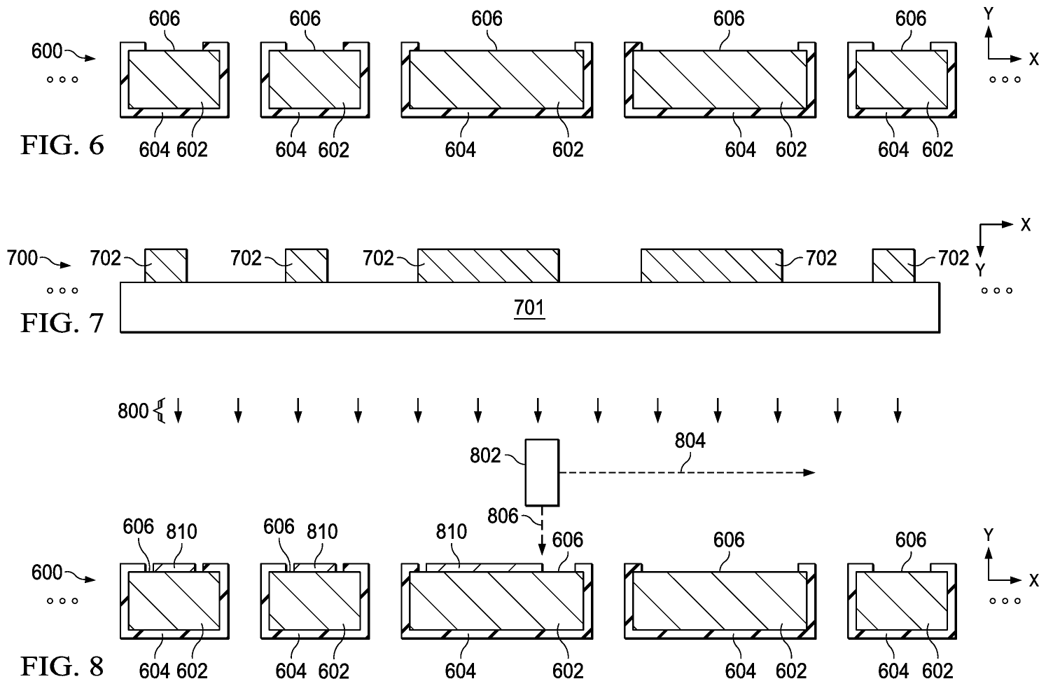

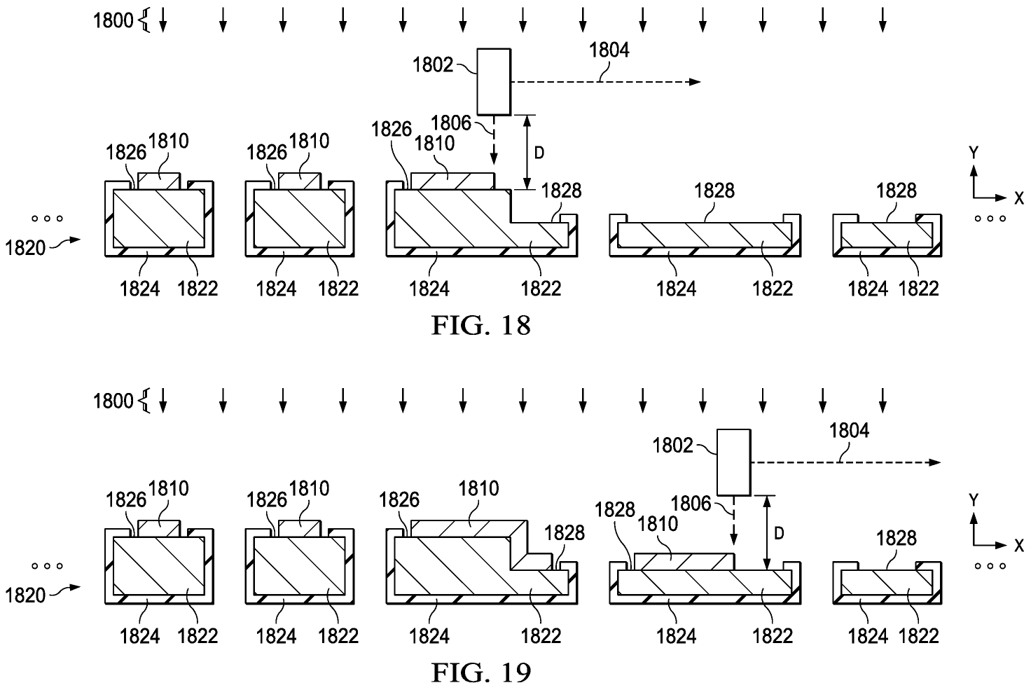

FIGS. 6-16 show a packaged electronic device undergoing fabrication according to the example method 100 of FIG. 1 with the implementation of FIG. 5. FIG. 6 shows a sectional side view of a portion of a fabricated lead frame 600 (e.g., fabricated at 102 in FIG. 1). The lead frame in one example is a sheet or strip having multiple die areas that are ultimately separated from one another (singulated), but which remain integrated during certain steps of an integrated circuit manufacturing process. In one example, the lead frame 600 is fabricated as a selectively coated copper structure with copper portions 602 and an oxide layer or coating 604 on select outer surfaces of the metal structure 602. The patterned copper metal structure 602 is formed in one example using stamping steps to construct die attach pads, leads and other features. Certain examples include uneven surfaces, for example, formed by etching select portions of a stamped copper structure to form step features to promote molding compound adhesion in finished integrated circuit products (e.g., FIGS. 18 and 19 below). In one example, the stamped structure is exposed to an oxidizing environment at a controlled temperature to form a copper oxide layer 604 CuₓO, such as cupric oxide (CuO) or cuprous oxide (Cu₂O). FIG. 7 shows a sectional side view of a die portion 700 of a processed semiconductor wafer (e.g., fabricated at 104 in FIG. 1). The die portion 700 includes a semiconductor portion 701 (e.g., silicon) and conductive features 702 (e.g., copper pads or posts). As previously discussed, the solder printing, flux application and engagement of the lead frame 600 with the die portion 700 can be performed either before or after die singulation (e.g., at 105 or 107 in FIG. 1). In a WCSP implementation, the die separation is concurrent with the device separation (e.g., at 116 in FIG. 1), and the lead frame or dielectric/RDL structure and processed wafer are engaged and the solder reflowed (e.g., 110 and 112 in FIG. 1) before molding and device separation.

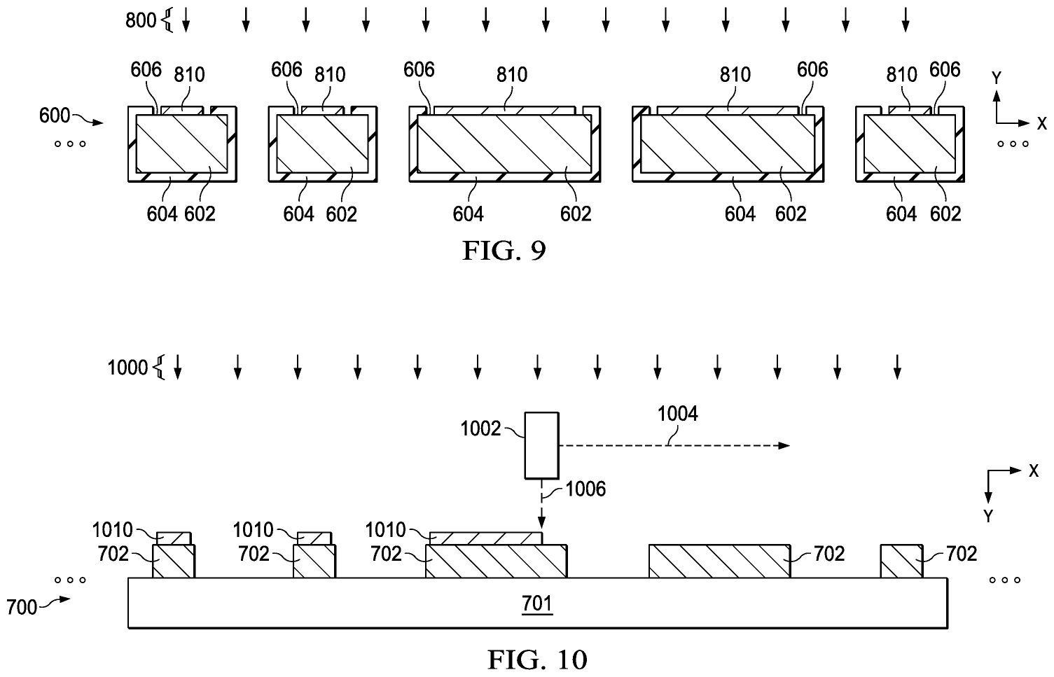

FIGS. 8 and 9 show one example, in which a non-screen printing process 800 is performed using a print head 802 that is controlled to translate along a controlled lateral direction or path 804 while directing solder along a vertical direction 806 toward the top side of the lead frame 600 to deposit solder 810 on the lead frame 600. In one example, the process is performed with an inkjet print head 802 having position control apparatus such as servo controls configured to translate, and control the position of, the print head 802 in three dimensions (e.g., the X and Y directions shown in the figures and an orthogonal Z direction out of the page in FIGS. 8 and 9). In one implementation, the printing system translates the print head 800 in an X-Z plane while controlling the Y direction spacing between the top side of the lead frame 600 and the print head 802. The printing system in one example also controls the delivery of solder from a nozzle of the print head to turn the printing on and off, for example, to facilitate precise, high resolution control over locations where the solder 810 is printed and where it is not printed. In addition, the non-screen printing process 800 provides control over the deposited solder thickness (e.g., in the Y direction) through one or more of deposition rate and controlling the time the print head 802 is positioned over a particular area of the lead frame 600. This facilitates printing solder to different thicknesses at different locations in certain implementations. In one example, the print head 802 is translated in the X-Z plane along a raster scan path 804 while spaced along the Y direction by a controlled distance above the top side of the lead frame 600 while printing a continuous or pulsed stream of solder 810. In certain implementations (e.g., at 200 in FIG. 2 above), the non-screen printing process 800 deposits the solder 810 mixed with flux.

The non-screen printing process 800 deposits (e.g., prints) solder 810 on select portions of the upper side of the lead frame 600 as shown in FIGS. 8 and 9. Different implementations include fine printing, for example, to print feature sizes of about 200 μm or more. In the illustrated example, the non-screen printing process 800 is an inkjet printing process. An inkjet implementation of the non-screen printing process 800 is advantageous for efficiently printing feature sizes on the order of 100's of microns down to 10-50 microns. In another example, the non-screen printing process 800 is an electrostatic printing process. An electrostatic jet printing implementation of the non-screen printing process 800 provides finer resolution, for example, to print feature sizes down to 10-50 μm or further down to the sub-micron level. In one example the non-screen printing process 800 deposits the solder 810 as an alloy mixture of melted particles using a heated print head 802, for example, with a printing temperature controlled to be above a melting temperature of the alloy particles. In one implementation, the non-screen printing process 800 deposits the solder 810 as an alloy of tin (Sn), silver (Ag), and copper (Cu), such as SAC 305 solder or SAC 405 solder, using a print head 802 provided with tin, silver and copper particles, and heated to a temperature at or above the melting temperatures of tin, silver and copper. In another implementation, the non-screen printing process 800 deposits the solder 810 as an alloy by printing melted first particles using a heated first print head 802 and printing melted second particles using a heated second print head 802. In another implementation, the non-screen printing process 800 deposits an alloy of three metals (e.g., tin, silver, and copper) using separate heated print heads 802 with respective melted tin, silver, and copper.

In another example, the non-screen printing process 800 deposits the solder 810 as particles in a solvent (e.g., dispersant), such as water, oil, ethanol, etc. In one implementation of this example, the print head 802 is not heated. In one example, the non-screen printing process 800 deposits the solder 810 as an alloy mixture of different particles in the solvent, such as a mixture of tin, silver and copper in water, oil, ethanol, or other solvent, with or without heat. In another implementation of this example, the non-screen printing process 800 deposits the solder 810 using a first print head 802 that deposits first particles in a first solvent, and a second print head 802 that deposits second particles in a second solvent. In one example, the non-screen printing process 800 uses a third print head 802 that deposits third particles in a third solvent. The solvents may be the same or may be different in various implementations. In one example, the non-screen printing process 800 deposits the solder 810 using a first print head 802 that deposits tin particles in a first solvent, a second print head 802 that deposits silver particles in a second solvent, and a third print head 802 that deposits copper particles in a third solvent. In one implementation, the three alloy components are sequentially printed, and the solvent evaporates (or is baked, such as at 501 in FIG. 5 above) to form the printed alloy solder 810. In one example, the non-screen printing process 800 controls the particle concentrations of the constituent alloy particles in the individual print heads, and/or the printing thicknesses of the constituent printed layers, to control the final alloy stoichiometry.

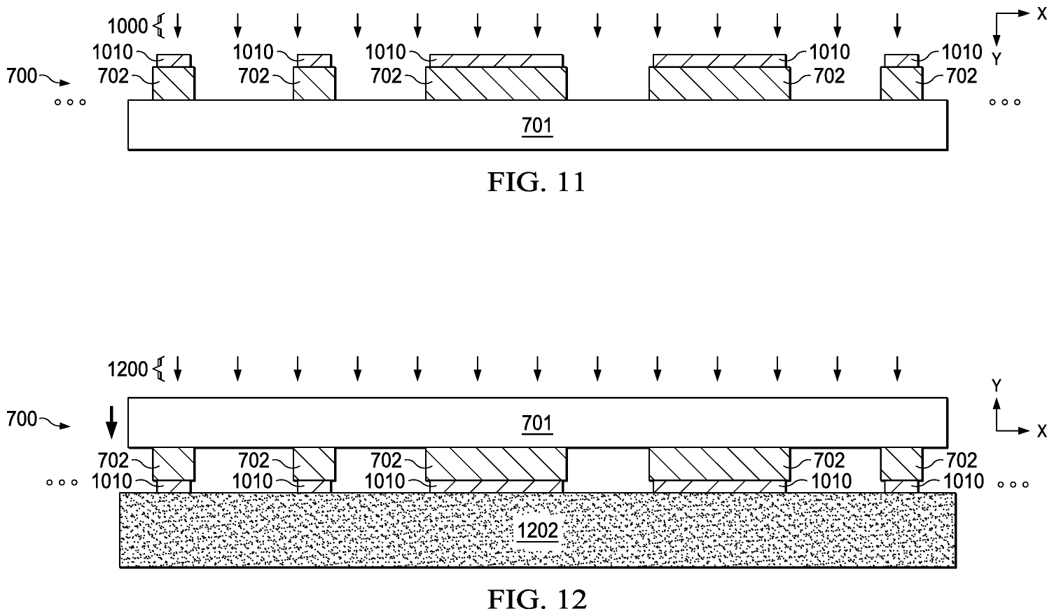

FIGS. 10 and 11 show one example, in which a non-screen printing process 1000 is performed using a print head 1002 that is controlled to translate along a controlled lateral direction or path 1004 while directing solder along a vertical direction 1006 toward the bottom side of the semiconductor die or wafer 700 to deposit solder 1010 on the die or wafer 700. In one example, the process 1000 is performed with an inkjet print head 1002 having position control apparatus such as servo controls configured to translate, and control the position of, the print head 1002 in three dimensions (e.g., the X and Y directions shown in the figures and an orthogonal Z direction out of the page in FIGS. 10 and 11). In one implementation, the printing system translates the print head 1000 in an X-Z plane while controlling the Y direction spacing between the top side of the die or wafer 700 and the print head 1002. The printing system in one example also controls the delivery of solder from a nozzle of the print head to turn the printing on and off, for example, to facilitate precise, high resolution control over locations where the solder 1010 is printed and where it is not printed. In addition, the non-screen printing process 1000 provides control over the deposited solder thickness (e.g., in the Y direction) through one or more of deposition rate and controlling the time the print head 1002 is positioned over a particular area of the die or wafer 700. This facilitates printing solder to different thicknesses at different locations in certain implementations. In one example, the print head 1002 is translated in the X-Z plane along a raster scan path 1004 while spaced along the Y direction by a controlled distance above the top side of the die or wafer 700 while printing a continuous or pulsed stream of solder 1010. In certain implementations (e.g., at 200 in FIG. 2 above), the non-screen printing process 1000 deposits the solder 1010 mixed with flux.

The printing process 1000 deposits (e.g., prints) solder 1010 on select portions of the upper side of the die or wafer 700 as shown in FIGS. 10 and 11. In the illustrated example, the non-screen printing process 1000 is an inkjet printing process. In another example, the printing process 1000 is an electrostatic printing process. In one example the non-screen printing process 1000 deposits the solder 1010 as an alloy mixture of melted particles using a heated print head 1002, for example, with a printing temperature controlled to be above a melting temperature of the alloy particles. In one implementation, the non-screen printing process 1000 deposits the solder 1010 as an alloy of tin, silver and copper using a print head 1002 provided with tin, silver and copper particles, and heated to a temperature at or above the melting temperatures of tin, silver and copper. In another implementation, the non-screen printing process 1000 deposits the solder 1010 as an alloy by printing melted first particles using a heated first print head 1002 and printing melted second particles using a heated second print head 1002. In another implementation, the non-screen printing process 1000 deposits an alloy of three metals (e.g., tin, silver, and copper) using separate heated print heads 1002 with respective melted tin, silver, and copper.

In another example, the non-screen printing process 1000 in FIGS. 10 and 11 deposits the solder 1010 as particles in a solvent (e.g., dispersant), such as water, oil, ethanol, etc. In one implementation of this example, the print head 1002 is not heated. In one example, the non-screen printing process 1000 deposits the solder 1010 as an alloy mixture of different particles in the solvent, such as a mixture of tin, silver and copper in water, oil, ethanol, or other solvent, with or without heat. In another implementation of this example, the printing process 1000 deposits the solder 1010 using a first print head 1002 that deposits first particles in a first solvent, and a second print head 1002 that deposits second particles in a second solvent. In one example, the non-screen printing process 1000 uses a third print head 1002 that deposits third particles in a third solvent. The solvents may be the same or may be different in various implementations. In one example, the non-screen printing process 1000 deposits the solder 1010 in three passes using a first print head 1002 that deposits tin particles in a first solvent, a second print head 1002 that deposits silver particles in a second solvent, and a third print head 1002 that deposits copper particles in a third solvent. In one implementation, the three alloy components are sequentially printed using respective print heads 1002 and associated solvents, and the solvent evaporates (or is baked, such as at 501 in FIG. 5 above) to form the printed alloy solder 1010 on the copper posts. In one example, the non-screen printing process 1000 controls the particle concentrations of the constituent alloy particles in the individual print heads, and/or the printing thicknesses of the constituent printed layers, to control the final alloy stoichiometry.

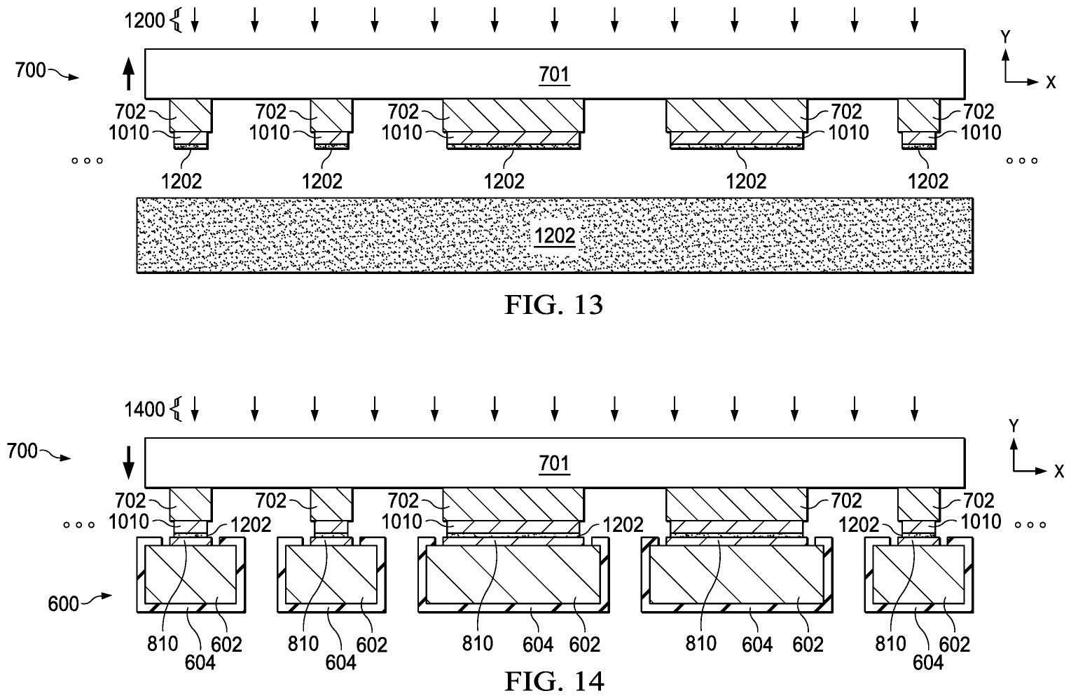

FIGS. 12 and 13 show a flux dipping process 1200 that dips the die or wafer 700 to form flux 1202 on the printed solder 1010 on the copper posts 702 (e.g., at 502 in FIG. 5 above). In this example, the die or wafer 700 is inverted with the copper posts 702 and printed solder 101 facing downward. The die or wafer 700 is then lowered to dip the ends of the solder printed copper posts 702 into a container of liquid flux 1202 as shown in FIG. 12, and then raised as shown in FIG. 13 to leave a dipped layer of flux 1202 on the bottom side of the printed solder 1010 on the bottoms of the copper posts 702.

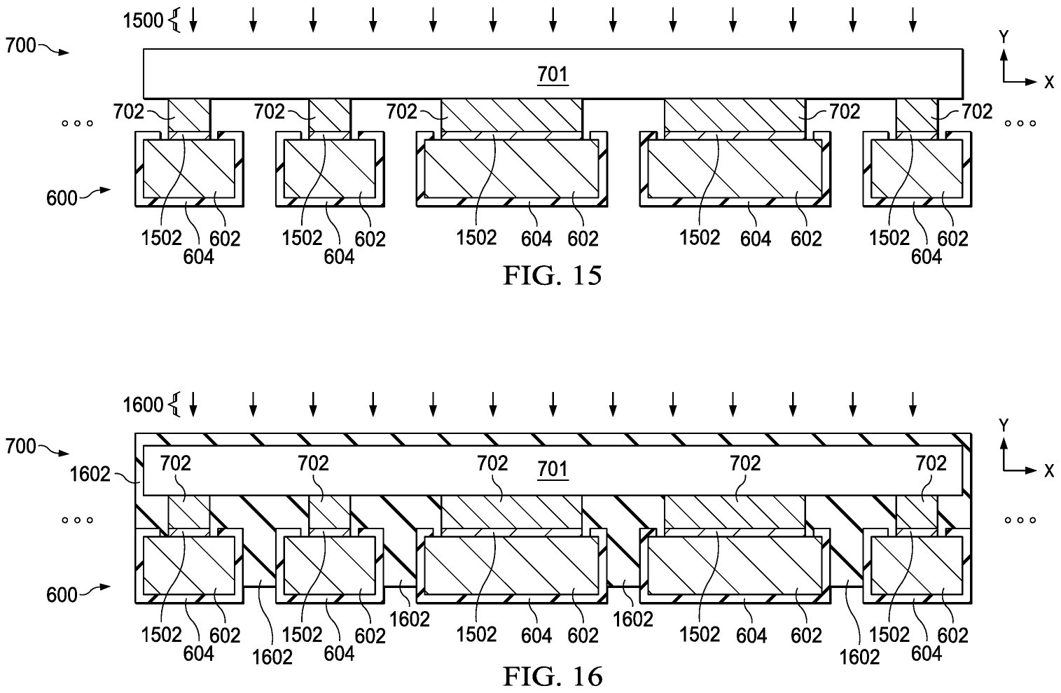

FIGS. 14 and 15 show attachment of the semiconductor die 700 and the lead frame 600, including an engagement process 1400 in FIG. 14 that engages the semiconductor die 700 to the lead frame 600 (e.g., 110 in FIG. 1 above). In the illustrated example, the solder printed lead frame 600 is positioned in a fixture, and the flux dipped die or wafer 700 is lowered onto the lead frame 600 to engage the flux dipped bottoms of the printed solder 1010 to the printed solder 810 of the lead frame 600 as shown in FIG. 14. FIG. 15 shows a thermal process 1500 (e.g., at 112 in FIG. 1) that melts the solder 810 and 1010 and reflows the solder 810 and 1010 with the flux 1202 of FIG. 14 to form a solder joint 1502 between the opposing faces of the copper posts 702 and portions of the top sides of the lead frame copper portions 602.

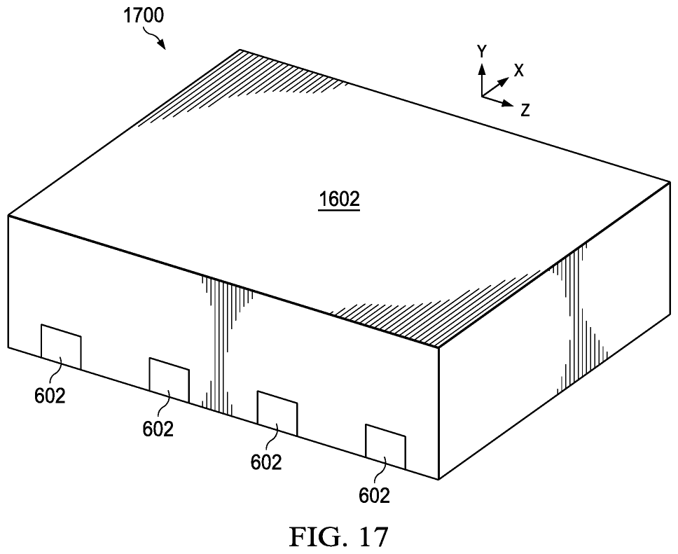

FIG. 16 shows a molding process 1600 (e.g., at 114 in FIG. 1) that forms a package structure 1602 (e.g., molding compound), which encloses the semiconductor die 700 and a portion of the lead frame 600. In this example, portions of lead features 602 are exposed outside the molded package structure 1602 to allow soldering of the finished IC packaged electronic device to a host printed circuit board (not shown). FIG. 17 shows an example of a finished packaged electronic device 1700 following respective device separation of the packaged electronic device 1700 from a remaining portion of the lead frame 600, and any final testing at 116 and 118 in FIG. 1.

Referring now to FIGS. 18-20, the non-screen solder printing in further examples includes performing a non-screen printing process that deposits solder on an uneven surface of a lead frame or on an uneven surface of a lead of a packaged electronic device. In one example, the non-screen printing process prints solder (e.g., SAC solder) on surfaces with an average roughness of about 100 μm or more, to accommodate solder printing on half-etched lead frames and lead features thereof, including saw cut tapered surfaces of a lead feature in some implementations. FIGS. 18 and 19 show one example of a non-screen solder printing process 1800 using a print head 1802 that is controlled to translate along a controlled lateral direction or path 1804 while directing solder along a vertical direction 1806 to deposit solder 1810 on the top side of a half-etched lead frame 1820. The lead frame 1820 in one example is a sheet or strip having multiple die areas that are ultimately separated from one another (singulated), but which remain integrated during certain steps of an integrated circuit manufacturing process. In one example, the lead frame 1820 is fabricated as a selectively coated copper structure with copper portions 1822 and an oxide layer or coating 1824 on select outer surfaces of the metal structure 1822. The patterned copper metal structure 1822 is formed in one example using stamping steps to construct die attach pads, leads and other features. In addition, portions of the top side of the lead frame are etched to approximately half the Y-direction thickness of other portions (e.g., half etched) to provide an uneven surface of the lead frame 1820 or on an uneven surface of a lead of a packaged electronic device fabricated using the lead frame 1820. Various implementations of the non-screen printing process 1800 are used in different examples, such as inkjet printing, electrostatic printing processes, etc., with a single or multiple print heads 1802, with or without heat, with or without solvents, and with or without flux, for example, as described for the printing processes 800 and 1000 described above. In addition, the non-screen printing process 1800 is used in various implementations to print any types of solder, including alloys, such as SAC solder as described above.

The non-screen printing process 1800 in FIGS. 18 and 19 deposits the solder 1810 on the step feature uneven surface of the lead frame 1820. In this example, the lead frame 1820 includes uneven surfaces of a lead 1822 of the finished electronic device, formed by half etching during lead frame fabrication. The non-screen printing process 1800 in this example includes controlling a spacing distance D between the print head 1802 and the uneven surface of the lead frame 1820. As shown in FIG. 18, the non-screen printing process 1800 in one example prints the solder 1810 with a generally uniform thickness on the uneven surface of the lead of the packaged electronic device according to a contour of the uneven surface by controlling the spacing distance D. The non-screen printing process 1800 in one example controls or regulates the spacing distance D to a generally constant value according to Y axis position feedback information regarding the position of the print head relative to a base or fixture that holds the lead frame 1820. In one example, the nonuniform surface, such as the step features shown in the example of FIGS. 18 and 19 is programmed into the position control apparatus for the printing process 1800, and the position control apparatus adjust the Y axis position of the print head 1802 to maintain a generally constant spacing distance D. In certain implementations, the non-screen printing process 1800 includes controlling the delivery of solder from a nozzle of the print head 1802, including adjusting deposition rate in a generally continuous fashion to print the solder 1810 with different thicknesses in different locations on the lead frame 1820.

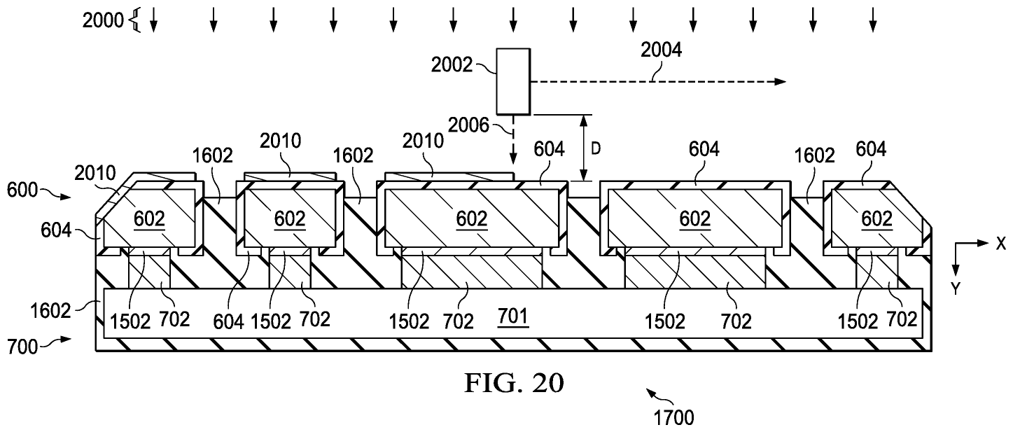

FIG. 20 shows a singulated packaged electronic device with saw cut leads having angled contours undergoing a non-screen solder printing process 2000 according to another example of the method 100 of FIG. 1. This example uses the lead frame 600 and semiconductor die portion 701 described above, where the outer side walls of lead features 602 of the starting lead frame 602 included chamfer, for example, formed during package separation sawing. In one example, the cut portion of the lead features 602 facilitate soldering to a host printed circuit board (not shown), allowing solder flow on the bottom of the lead feature 602 as well as along a portion of the sidewall of the lead feature 602. This facilitates fabricating a wettable, flank side, through controlled vertical and/or angled printing at a non-zero print angle relative to the top and bottom of the packaged electronic device structure.

As shown in FIG. 20, the non-screen printing process 2000 uses a print head 2002 that is controlled to translate along a controlled lateral direction or path 2004 while directing solder along the vertical direction 2006 to deposit solder 2010 on the top side of a singulated packaged electronic device. Various implementations of the non-screen printing process 2000 are used, such as inkjet printing, electrostatic printing processes, etc., with a single or multiple print heads 2002, with or without heat, with or without solvents, and with or without flux, for example, as described for the non-screen printing processes 800, 1000, and 1800 described above. In addition, the non-screen printing process 2000 is used in various implementations to print any types of solder, including alloys, such as SAC solder as described above. The non-screen printing process 2000 in this example prints the solder 2010 along the angled portions and horizontal portions of the lead features 602, including printing solder 2010 over any intervening coating material 604 in this example. The non-screen printing process 2000 in one example includes controlling a spacing distance between the print head 2002 and the uneven surface of the singulated packaged electronic device. As shown in FIG. 20, the non-screen process 2000 in one example prints the solder 2010 with a generally uniform thickness on the uneven surface of the lead of the packaged electronic device according to a contour of the uneven surface by controlling the spacing distance D. The non-screen printing process 2000 in one example controls or regulates the spacing distance D to a generally constant value according to Y axis position feedback information regarding the position of the print head relative to a base or fixture that holds the lead frame 2020. In one example, the nonuniform surfaces, such as the step features shown in the example of FIG. 20 are programmed into the position control apparatus for the non-screen printing process 2000, and the position control apparatus adjust the Y axis position of the print head 2002. In certain implementations, the non-screen printing process 2000 includes controlling the delivery of solder from a nozzle of the print head 2002, including adjusting deposition rate in a generally continuous fashion to print the solder 2010 with different thicknesses in different locations on the lead frame 600.

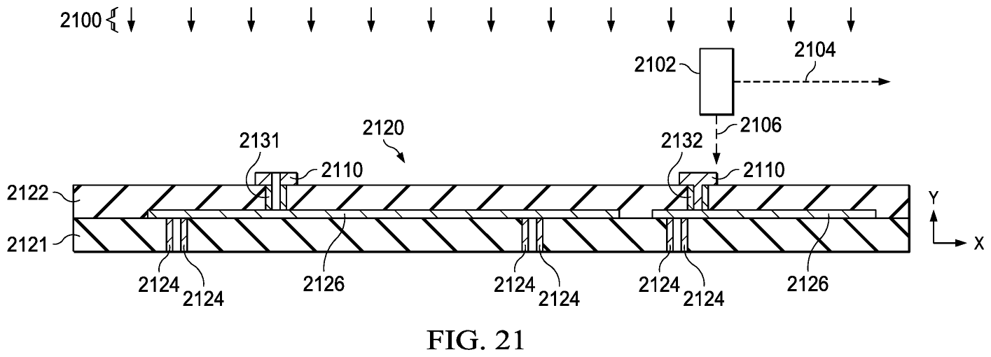

FIG. 21 shows another aspect, in which a non-screen solder printing process 2100 is performed that deposits solder 2110 on or in conductive vias 2131 and 2132 of a laminate structure 2120. In this example, the non-screen printing process 2100 uses a print head 2102 that is controlled to translate along a controlled lateral direction or path 2104 while directing solder along the vertical direction 2106 to deposit solder 2110 on or in vias of the laminate structure 2120. The laminate structure 2120 in this example includes a first dielectric layer 2121 and a second dielectric layer 2122. Conductive vias 2124 (e.g., copper) extend between top and bottom sides of the first dielectric layer 2121. Some of the vias 2124 are in contact with copper routing features 2126 (e.g., lines or traces) that extend between the top side of the first dielectric layer 2121 and a bottom side of the second dielectric layer 1222. The vias 2131 and 2132 extend between the bottom and top sides of the second dielectric structure 2122. Various implementations of the non-screen printing process 2100 are used, such as inkjet printing, electrostatic printing processes, etc., with a single or multiple print heads 2102, with or without heat, with or without solvents, and with or without flux, for example, as described for the printing processes 800, 1000, 1800, and 2000 described above. In addition, the non-screen printing process 2100 is used in various implementations to print any types of solder, including alloys, such as SAC solder as described above. The non-screen printing process 2100 in this example selectively prints solder 2110 on top edges of the first via 2131, where the solder 2110 in this example extends outward from a lip of the via 2131 along portions of the second dielectric layer 2122, but the solder 2110 is not printed in the interior cavity of the via 2131. The non-screen printing process 2100 in FIG. 21 prints the solder 2110 on the top edges of the second via 2132. In this example, the non-screen printing process 2100 also prints solder 2110 into the interior cavity of the second via 2132. In one example, the non-screen printing process 2100 controls the print head 2102 in order to remain over the center of the via 2132 for sufficient time to completely fill the interior cavity of the via 2132, although not a requirement of all possible implementations.

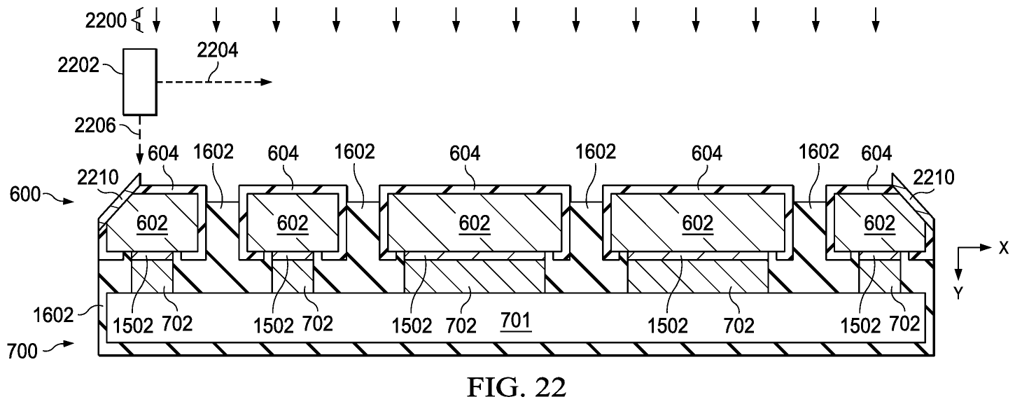

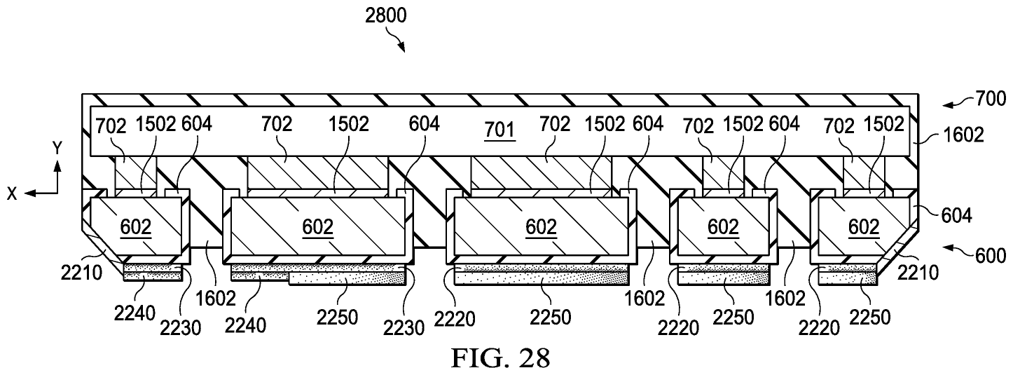

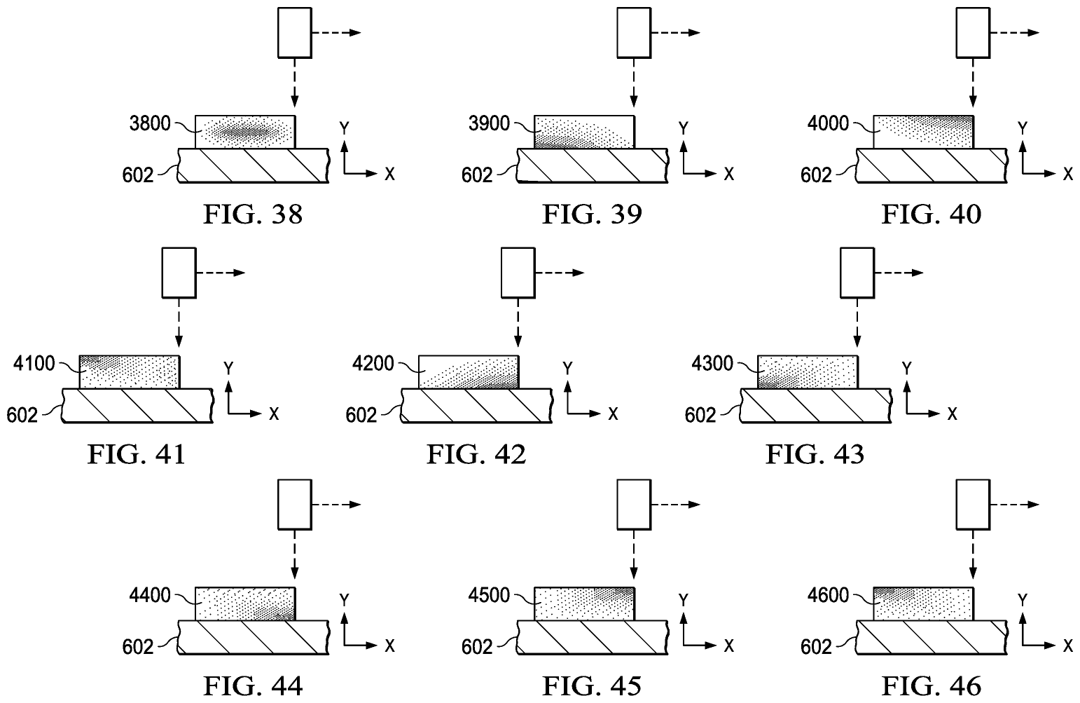

Referring now to FIGS. 22-46, FIGS. 22-27 show another singulated packaged electronic device undergoing solder printing deposition and thermal processing to form a packaged electronic device, including solder layers with profiled or varying ratios and constituent gradients laterally across the solder and/or vertically through the solder. FIG. 28 shows the finished packaged electronic device of FIGS. 22-27 with varying lateral and vertical constituent ratios across the solder and vertically through the solder. FIGS. 28-46 show partial sectional side views of further non-limiting examples of electronic devices with printed solder of different constituent profiles. The non-screen printing process in one example forms nanoparticles of two or more different constituent materials (e.g., tin-silver-copper (Sn, Ag, Cu)). The print deposition in this example forms individual Sn, Ag, and Cu particles mixed together, for example, by concurrent printing using separate print heads or printed separately. In one example, the above methods produce a printed solder by dispersing metal nanoparticles in a solution that is then print deposited, for example, by one or more print heads as previously described. The deposited nanoparticle film is not 100% dense upon deposition, and instead forms nanoparticles positioned on top of each other, for example, having diameters in the range of about 20 nm to 20 um.

Subsequent application of energy, such as heat, melts the nanoparticles together, for example, at low temperatures (e.g., approximately 80 degrees C.). The printing of such nanoparticles facilitates the SAC melt at an even lower temperature, which is a major advantage for manufacturing. The heating causes the nanoparticles to diffuse into each other and create a final solder structure, for example, a layer that includes co-diffused Sn, Ag, and Cu (or Sn(X)Ag(Y)Cu(Z) nanoparticles) of diameter 20 nm to 20 um. The solder layer in one example has varying SAC ratios across the film (e.g., Sn(X)Ag(Y)Cu(Z), where X, Y and/or Z vary laterally and/or vertically through the film. In one example, a packaged electronic device includes an SAC solder on a conductive structure. In certain examples, the solder extends on a lead frame, an IC terminal, a remaining portion of a starting lead frame after device or package singulation, a conductive pad or feature of a substrate, or a conductive pad or feature of a processed semiconductor wafer, or a conductive pad or feature of a singulated semiconductor die, etc. In certain examples, the solder is an SAC solder with a higher Ag ratio at the bottom of the film than at the top of the film, for example, formed by adjusting the Ag print head while keeping the Cu and Sn print heads jetting at the same volume per area. In other examples, two more constituent concentration ratios of the solder vary in one or two or three mutually orthogonal directions in a three-dimensional space, for example, including the X and Y directions in FIGS. 22-46 and/or any third (e.g., “Z”) direction or combinations thereof.

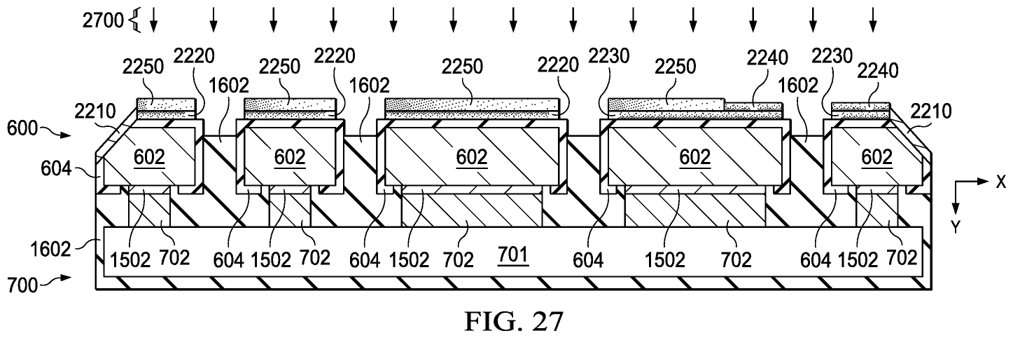

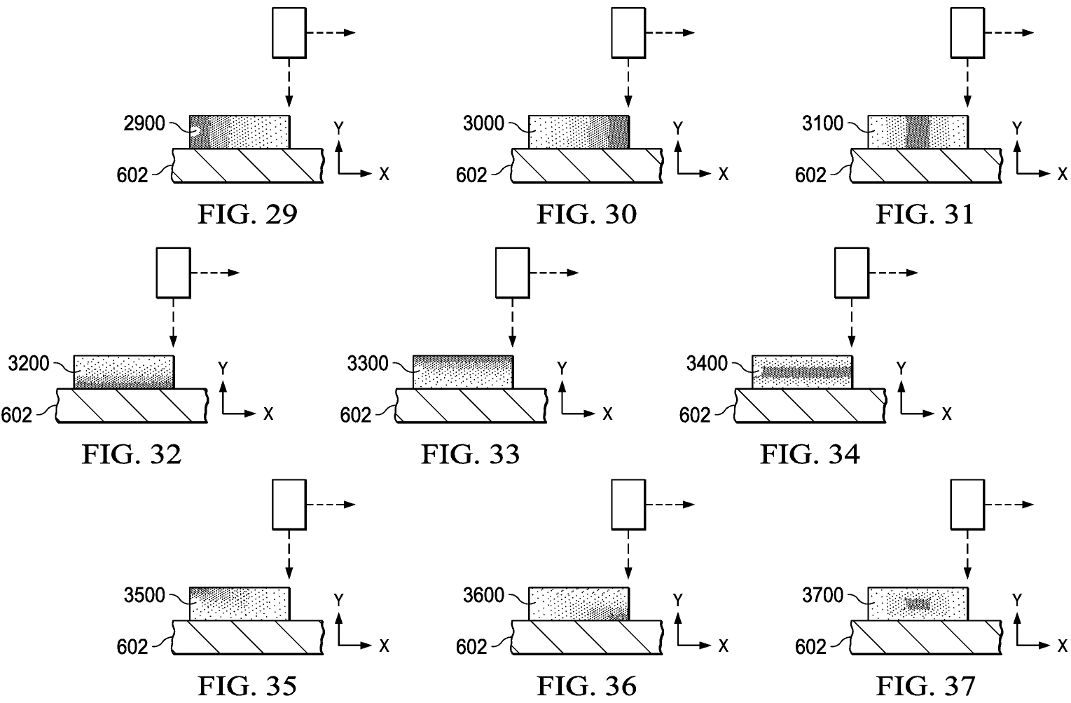

FIGS. 22-26 show example processing to produce a packaged electronic device during printing different solder sections, some of which have different ratios of tin, silver and copper, some of which are stacked to form vertical profiling, some are formed as profiled solder sections in different lateral areas for composite lateral profiling, and some with different thicknesses. FIG. 27 shows a thermal process after solder printing, and FIG. 28 shows the resulting finished packaged electronic product. FIGS. 29-46 to illustrate several non-limiting examples of profile ratios of two metal constituents of example printed and thermally co-diffused solder layers formed on respective conductive features of a packaged electronic device.

A non-screen solder printing process 2200 is illustrated in FIG. 22, which deposits an alloy of three metals (e.g., tin, silver, and copper) using separate heated print heads shown as a single unit 2204 translated along a lateral direction 2204 that deposits material along a print direction 2206 to form a first solder section 2210. FIG. 22 shows a singulated packaged electronic device with a package structure 1602 (e.g., molding compound), and saw cut leads having angled contours undergoing the non-screen solder printing process 2200. The example device in FIGS. 22-28 uses the lead frame 600 and semiconductor die portion 701 described above, where the outer side walls of lead features 602 of the starting lead frame 602 included chamfer, for example, formed during package separation sawing. In one example, the cut portion of the lead features 602 facilitate soldering to a host printed circuit board (not shown), allowing solder flow on the bottom of the lead feature 602 as well as along a portion of the sidewall of the lead feature 602. This facilitates fabricating a wettable, flank side, through controlled vertical and/or angled printing at a non-zero print angle relative to the top and bottom of the packaged electronic device structure.

As shown in FIG. 22, the non-screen printing process 2200 translates the print head unit 2202 along a controlled lateral direction or path 2204 while directing solder along the vertical direction 2206 to deposit solder 2010 on the angled portion of the top side of the singulated packaged electronic device. Various implementations of the non-screen printing process 2200 can be used, such as inkjet printing, electrostatic printing processes, etc., with a single or multiple print head units 2202, with or without heat, with or without solvents, and with or without flux, for example, as described for the non-screen printing processes 800, 1000, and 1800 described above. In addition, the non-screen printing process 2200 is used in various implementations to print any types of solder, including alloys, such as SAC solder as described above. The non-screen printing process 2200 in this example prints the solder section 2010 along the angled portions and horizontal portions of the lead features 602, including printing solder section 2010 over any intervening coating material 604 in this example. The non-screen printing process 2200 in one example includes controlling a spacing distance between the print head 2202 and the uneven surface of the lead features 602.

As shown in FIG. 22, the non-screen printing process 2000 in one example prints the solder section 2010 with a generally uniform thickness on the uneven surface of the lead of the packaged electronic device according to a contour of the uneven surface. In certain implementations, the non-screen printing process 2000 includes controlling the delivery of solder from a nozzle of the print head unit 2202, including adjusting deposition rate in a generally continuous fashion to print the solder section 2010 with different thicknesses in different locations on the lead frame 600.

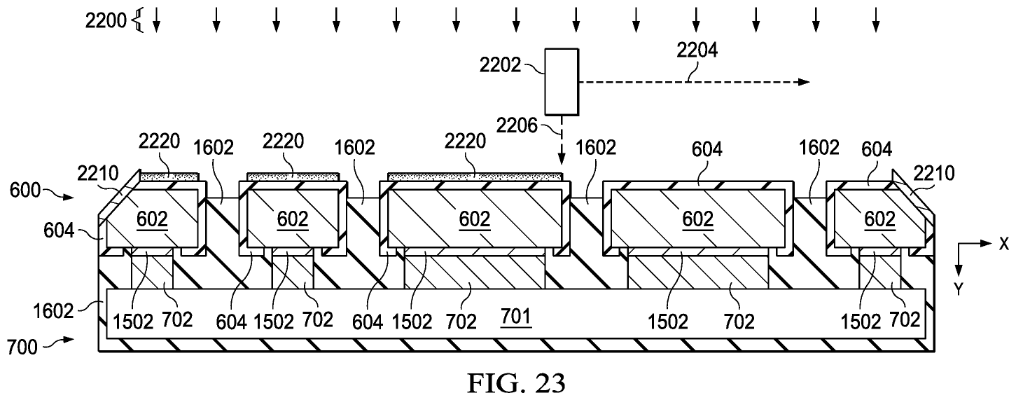

The process 2200 continues in FIGS. 23-26 to print further solder sections 2220, 2230, 2240 and 2250. These further solder sections show example profiled concentration ratios, including shading or dot density in the figures indicating generally continuously varying ratios of two of the three constituent metal materials that form the solder sections (e.g., a ratio of silver concentration divided by copper concentration, etc.). In specific examples, the concentration of any one of these three example metal constituent materials can vary from 0% to 100% in any linear, nonlinear, or stepped fashion in different examples. A second solder section 2220 is formed in FIG. 23, in this example including profile of silver concentration which is at or near 0% on the bottom of the solder section 2220 and increases toward or to 100% at or near the top of the solder section 2220. Although this and other profiled solder sections are generally illustrated in the drawings as being continuous, other profiles are possible, such as stepped profiles, etc. The vertical profiling illustrated in FIG. 23, in one example, is implemented by the print head unit 2202 modifying the mixture of the constituent metals dynamically at each lateral position in a single pass. In another possible implementations, the non-screen printing process 2200 implements vertical profiling (e.g., varying concentration ratio profiles along the direction of printing 2206) in a multi-pass fashion, for example, printing along the print direction 2204 with a first concentration ratio (e.g., silver concentration at or near 0%), and performing multiple repeated passes to gradually increase the thickness of the deposited solder section 2220 with incrementally increasing concentration ratios of silver, for example, with corresponding decreasing concentrations of the other two constituent metals of the solder 2220).

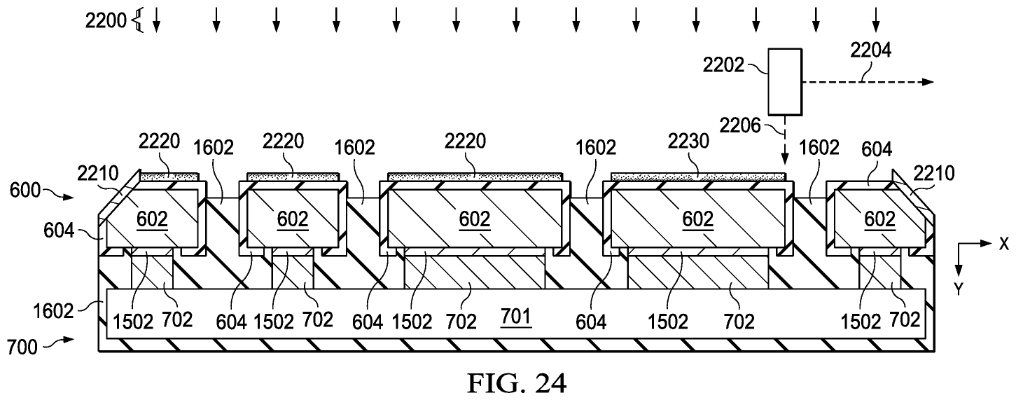

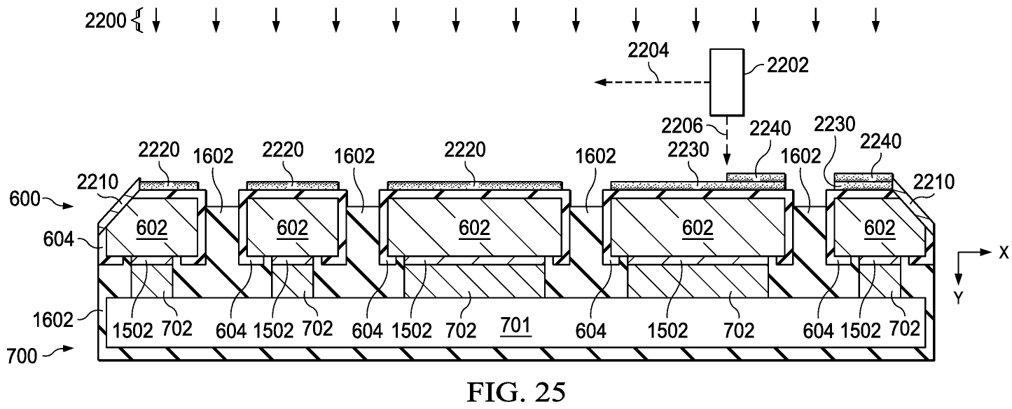

As shown in FIGS. 24 and 25, this example continues with the process 2200 further depositing third solder sections 2230, which have reversed vertical silver concentration profiles (e.g., at or near 100% on the bottom of the solder sections 2230, gradually decreasing to or near 0% at the top of the solder sections 2230). As further shown in FIG. 25, the process 2200 in this example also includes depositing fourth solder sections 2240 over portions of the third solder sections 2230. The example solder sections 2240 in this example also have vertical silver concentration profiles with higher silver concentrations at the bottom and lower silver concentrations at the top. The combination of the underlying profiled solder sections 2230 in the overlying profiled solder sections 2240 creates a composite vertically profiled solder structure 2230/2240 with concentration profiles of silver content along the vertical (Y) direction.

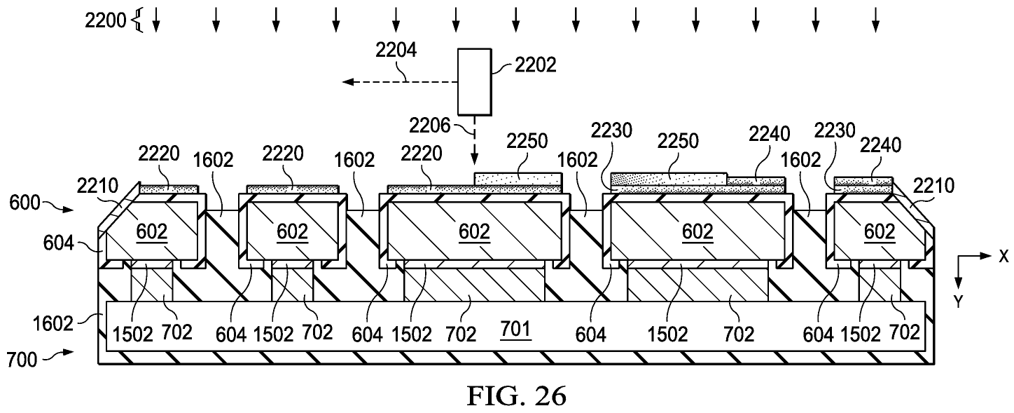

The process 2200 continues in FIGS. 26 and 27 to deposit fifth solder sections 2250 that individually include laterally profiled silver concentrations. In the illustrated example, as the print head unit 2202 is translated along the direction 2204 (e.g., to the left in FIGS. 26 and 27), the silver concentration increases in each of the printed sections 2250 (e.g., from at or near 0% on the right side ends of the sections 2250, to at or near 100% on the left side ends of the sections 2250). As further shown in FIGS. 26 and 27, the process 2600 prints the solder sections 2250 to a vertical thickness (e.g., along the Y direction) that is greater than the vertical thickness of the solder sections 2240. As previously discussed, the print deposition of the solder sections 2210, 2220, 2230, 2240 and 2250 provides a structure that includes individual Sn, Ag, and Cu particles mixed together, where the deposited nanoparticle film is not 100% dense upon deposition, and instead forms nanoparticles positioned on top of each other, for example, having diameters in the range of about 20 nm to 20 um.

A thermal heating process 2700 is performed in FIG. 27 that applies energy to the printed solder segments 2210, 2220, 2230, 2240 and 2250, which melts the nanoparticles together. In one example, the thermal process controls the temperature of the deposited solder sections to a low temperature, such as at or near 80° C. (e.g., +/−2° C.), which diffuses the nanoparticles into each other and creates final solder section structures 2210, 2220, 2230, 2240 and 2250 in FIGS. 27 that respectively include co-diffused Sn, Ag, and Cu (or Sn(X)Ag(Y)Cu(Z) nanoparticles) of diameter 20 nm to 20 um in the resulting finished packaged electronic device 2800 illustrated in FIG. 28.

FIGS. 29-46 illustrate several non-limiting examples of profile ratios of two metal constituents of example printed and thermally co-diffused solder layers formed on respective conductive features of a packaged electronic device. In these examples, dark areas having high dot density indicate high concentration ratio of silver to the concentration of the other constituent metals tin and copper for an SAC solder example, and light areas having no or low dot density indicate low concentration ratio of silver to the other constituent metal concentrations. Different profiled printed solder section implementations include variations in more than one constituent metal relative to the other metals, and any number of ratio metric profiles, of any desired shape, gradient, etc., can be implemented in different example packaged electronic devices, including stepped, nonlinear, linear, exponential profiles, etc. The packaged electronic device examples of FIGS. 29-46 are nonlimiting, and merely illustrative of several of the many possible implementations, in which a solder structure 2900, 3000, 3100, 3200, 3300, 3400, 3500, 3600, 3700, 3800, 3900, 4000, 4100, 4200, 4300, 4400, 4500, and 4600 is or are formed on a conductive structure 602, such as a lead frame, an IC terminal, a remaining portion of a starting lead frame after device or package singulation, a conductive pad or feature of a substrate, or a conductive pad or feature of a processed semiconductor wafer, or a conductive pad or feature of a singulated semiconductor die, etc.

Described examples provide solder printing, such as SAC solder printed using inkjet or electrostatic printing processes that facilitate electronic device manufacturability and performance improvements. Some described examples facilitate variation in printed materials in one pass using multiple nozzles, such as printed solder, flux, and solder mask. Certain implementations also facilitate controlled variation in printed material thickness, for example, using inkjet or electrostatic printing to compensate for post size or other differences with solder thickness. The described techniques, moreover, facilitate use of different, unplated copper lead frame materials, together with the improved current carrying capability of solder alloys such as SAC solder. The described non-screen printing processes allow use of solders that cannot be plated and provide improved control, positioning, process throughput and flexibility for precise control of printed area feature size and thickness. In addition, the described examples facilitate placement of capacitors and inductors at the same time as semiconductor dies, even though such passive components may have different solder requirements than the semiconductor dies. As described above, many different implementations are possible, including printing solder particles and flux as a suspension, printing solder particles first followed by printing flux, printing solder particles followed by flux dip, and printing solder particles, baking the printed solder particles, and then printing flux or flux dipping. Printing processes and equipment can be changed with updated software with little or no cost impact for retooling, labor, or materials, and provide advantages over screen printing in terms of adaptability. The printing techniques can be used instead of plating, thereby enabling larger posts and denser copper on silicon without the cost of lead frame plating during fabrication, while improving thermal conductance through the lead frame compared with plated tin lead solder (e.g., 360 W/mK vs 190 W/mK watts per meter). Moreover, the described non-screen printing processes allow depositing thicker solder in some locations, for example, to account for different size copper posts on semiconductor dies to achieve better final device planarity, and inkjet or other non-screen printing processes facilitate placing other components with different solder requirements. Moreover, solder resist printing facilitates for optimum flow during device manufacturing. In addition, inkjet, electrostatic or other non-screen printing processes use much less material than screening, and printing avoids can be used in combination with selective heating, while avoiding problems associated with stencils getting dirty, smeared, stretched or other stencil defects or degradation. Moreover, printing can be used to print on non-planar surfaces (e.g., cavities, lead flanks, half-etch lead frame features, etc.), and printing can print directly onto die posts or pillars. As described above, certain examples also facilitate printing thru-silicon vias. In addition, automated printing is fast, for example, allowing printing solder on select locations of a processed wafer in 30 seconds or less. In addition, multiple print heads can perform a single alloy printing, with or without heat, and with or without solvent, as a single operation, whereas stencil or screening techniques involve multiple operations and use much more material.

The above examples are merely illustrative of several possible implementations of various aspects of the present disclosure, wherein equivalent alterations and/or modifications will occur to others skilled in the art upon reading and understanding this specification and the annexed drawings. Modifications are possible in the described examples, and other implementations are possible, within the scope of the claims.

1. A method, comprising:
performing a non-screen printing process that deposits solder on a lead frame or on conductive features of a semiconductor die or wafer;
engaging the semiconductor die to the lead frame;
performing a thermal process that reflows the solder;
performing a molding process that forms a package structure, which encloses the semiconductor die and a portion of the lead frame; and
separating a packaged electronic device from a remaining portion of the lead frame.

2. The method of claim 1, further comprising:
after performing the non-screen printing process and before engaging the semiconductor die to the lead frame, depositing flux on the solder.

3. The method of claim 2, wherein depositing the flux on the solder comprises performing a second non-screen printing process that deposits the flux on the solder.

4. The method of claim 1, wherein the non-screen printing process deposits the solder mixed with flux.

5. The method of claim 1, wherein the non-screen printing process deposits the solder as an alloy of tin (Sn), silver (Ag), and copper (Cu).

6. The method of claim 1, wherein the non-screen printing process deposits the solder as an alloy mixture of melted particles using a heated print head.

7. The method of claim 1, wherein the non-screen printing process deposits the solder as particles in a solvent.

8. The method of claim 7, wherein the non-screen printing process deposits the solder as an alloy of tin (Sn), silver (Ag), and copper (Cu).

9. The method of claim 8, wherein the non-screen printing process deposits the solder using: a first print head that deposits tin particles in a first solvent; a second print head that deposits silver particles in a second solvent; and a third print head that deposits copper particles in a third solvent.

10. The method of claim 1, wherein the non-screen printing process deposits the solder as an alloy by: printing melted first particles using a heated first print head; and
printing melted second particles using a heated second print head.

11. The method of claim 1, wherein the non-screen printing process is an inkjet printing process.

12. The method of claim 1, wherein the non-screen printing process is an electrostatic printing process.

13. The method of claim 1, wherein the non-screen printing process deposits the solder using: a first print head that deposits first particles in a first solvent; and a second print head that deposits second particles in a second solvent.

14. A method, comprising:
performing a non-screen printing process that deposits solder on an uneven surface of a lead frame or on an uneven surface of a lead of a packaged electronic device.

15. The method of claim 14, wherein the non-screen printing process is an inkjet printing process.

16. The method of claim 14, wherein the non-screen printing process is an electrostatic printing process.

17. The method of claim 14, wherein performing the non-screen printing process comprises:
controlling a spacing distance between a print head and the uneven surface of the lead frame or the uneven surface of the lead of the packaged electronic device according to a contour of the uneven surface.

18. A method, comprising:
performing a non-screen printing process that deposits solder on or in a conductive via of a laminate structure.

19. The method of claim 18, wherein the non-screen printing process is an inkjet printing process.

20. The method of claim 18, wherein the non-screen printing process is an electrostatic printing process.

21-25. (canceled)

26. A method, comprising:
providing a conductive structure of a lead frame or semiconductor die or wafer or substrate; and
forming a solder layer on the conductive structure, the solder layer comprising co-diffused metallic nanoparticles of two metals, the nanoparticles having respective diameters of 20 nm or more and 20 um or less.

27. The method of claim 26, wherein a ratio of concentrations of the two metals in the solder layer varies along at least one direction.

28. The method of claim 27, wherein:
the solder layer comprises co-diffused metallic nanoparticles of tin, silver, and copper; and
a ratio of concentrations of two of tin, silver, and copper in the solder layer varies along the at least one direction.

29. The method of claim 28 wherein the ratio of concentrations of the two of tin, silver, and copper in the solder layer varies along two or more mutually orthogonal directions.

30. The method of claim 26, wherein a ratio of concentrations of the two metals in the solder layer varies along two or more mutually orthogonal directions.
